(19) United States
(12) Patent Application Publication
(10) Pub. No.: US 2015/0159048 A1
(43) Pub. Date: Jun. 11, 2015

(54) POLISHING COMPOSITION AND POLISHING METHOD

(71) Applicant: Asahi Glass Company, Limited, Chiyoda-ku (JP)

(72) Inventor: Iori YOSHIDA, Chiyoda-ku (JP)

(73) Assignee: Asahi Glass Company, Limited, Chiyoda-ku (JP)

(21) Appl. No.: 14/522,943

(22) Filed: Oct. 24, 2014

(30) Foreign Application Priority Data
Dec. 9, 2013 (JP) 2013-254341

(51) Int. Cl. C09G 1/02; H01L 21/306

(52) U.S. Cl. CPC C09G 1/02; H01L 21/30625

(57) ABSTRACT

A polishing composition contains cerium oxide particles of 50 nm or more to 160 nm or less in average secondary particle diameter and at least one kind of nitride film polishing accelerating agent selected from a group consisting of a methonium compound and a primary or secondary alkanolamine compound, wherein a concentration of the methonium compound is 1.0 mass % or less, and a pH is 3.5 or more to less than 6. A polishing method includes bringing a surface to be polished of an object into contact with a polishing pad while a polishing composition according to claim 1 is supplied to the polishing pad, and polishing by a relative movement between the surface of the object and the polishing pad.

### CROSS REFERENCE TO RELATED APPLICATION

This application is based upon and claims the benefit of priority from the prior Japanese Patent Application No. 2013-254341, filed on Dec. 9, 2013; the entire contents of which are incorporated herein by reference.

### FIELD

The present invention relates generally to a polishing composition used for a manufacturing process of a semiconductor integrated circuit (hereinafter, also referred to as a semiconductor device), and more specifically, relates to a polishing composition suitable for polishing a surface to be polished of a semiconductor device substrate on which a silicon-based material which includes a silicon nitride or a silicon oxynitride and a silicon oxide is film-formed, the semiconductor device substrate being used for gate formation in a multilayer wiring forming process or the like, and a polishing method using the same.

### BACKGROUND

In recent years, because of a tendency of high integration/high function of a semiconductor integrated circuit, development of a microfabrication technique for miniaturization/high concentration has been demanded. In particular, a planarization technique by chemical mechanical polishing (hereinafter, referred to as CMP) is becoming important. As miniaturization of a semiconductor device and multilayering of wirings advance, for example, unevenness (level difference) of a surface in each layer in a manufacturing process is apt to become large. In order to prevent a problem that the level difference exceeds a depth of focus of photolithography and hampers obtaining a sufficient resolution, CMP is an indispensable technique and is used for planarization of an inter-level dielectrics (ILD), shallow trench isolation (STI), tungsten plug formation, a forming process of multilayer wirings constituted with copper and a low dielectric constant film, and so on. Planarization by CMP is also performed in a capacitor, a gate electrode, and so on in a multilayer wiring forming process.

For example, in fabrication of a metal gate field effect transistor, a MISFET (Metal insulator semiconductor field effect transistor) structure by a dummy gate electrode is formed in advance, a cobalt silicide film is formed, and an entire surface is covered by a silicon nitride film. Further, a thick silicon oxide film is formed. Thereafter, the silicon oxide film and the silicon nitride film are selectively removed by CMP, and the surface is planarized. Thereby, a surface of the dummy gate electrode is exposed. Next, the dummy gate electrode is removed, a gate insulation film is formed by thermal oxidation, a metal film of W or the like is formed on the entire surface, and an extra metal film of a portion other than a gate unit is removed by CMP, so that a metal gate is formed (refer to Patent Publication JP-B2 No. 3175700, for example).

Further, in a gate forming process in a transistor after 45 nm generation, in recent years, there are studied application of a high dielectric constant material (high-k film) to a gate insulation film and application of a metal material to a gate electrode instead of conventional polysilicon having been doped with impurities.

For example, application of a polishing method is suggested in which after fabrication of a dummy gate structure using polysilicon, a silicon oxide film covering a gate surface is planarized by CMP as first-stage polishing, the silicon oxide film and a silicon nitride film being a hard mask are polished as second stage polishing, to perform exposure of a dummy gate electrode of polysilicon.

However, in the second stage polishing process, there is a problem that a silicon oxide film is excessively polished during removal of the silicon nitride film since a polishing speed of the silicon nitride film is quite low in relation to a polishing speed of the silicon oxide film (refer to US 2010/0048007A1, for example).

To cope with such a problem, as a polishing composition suitable for polishing of a silicon nitride film, there is suggested a polishing liquid for silicon nitride film which contains colloidal silica, an organic acid having at least one sulfonic acid group or phosphonic acid group in a molecular structure and functioning as a polishing accelerating agent to a silicon nitride film, and water, and whose pH is 2.5 to 5.0 (refer to JP-A 2010-41037, for example). The polishing composition described in Japanese Patent Application Laid-open No. 2010-41037 is alleged to be high in polishing speed of a layer containing a silicon nitride and to be able to suppress polishing of a layer containing a silicon-based compound such as polysilicon selectively. However, the polishing speed of the silicon nitride film is still insufficient, and there is a problem that a polishing time is long, reducing a throughput of a related polishing process.

### BRIEF DESCRIPTION OF THE DRAWINGS

FIG. 1 is a view showing an example of a polishing apparatus usable for a polishing method of the present invention.

### DETAILED DESCRIPTION

The present invention has been made to solve the aforementioned problem and its object is to provide a polishing composition which is used for polishing of a surface to be polished of a semiconductor substrate on which a silicon-based material which includes a silicon nitride or a silicon oxynitride and a silicon oxide is film-formed and which polishes at a high polishing speed and at a suitable polishing speed ratio to perform planarization, and a polishing method using the same.

The polishing composition of the present invention contains cerium oxide particles and at least one kind of nitride film polishing accelerating agent selected from a group consisting of a methonium compound and an alkanolamine compound, wherein the alkanolamine compound is a primary or secondary alkanolamine compound, an average secondary particle diameter of the cerium oxide particles is 50 nm or more to 160 nm or less, a concentration of the methonium compound is 1.0 mass % or less, and a pH is 3.5 or more to less than 6.

In the polishing composition of the present invention, the number of carbon of a main chain of the methonium compound is preferable to be 2 to 7. Further, the polishing composition of the present invention is preferable to contain the methonium compound and in the polishing composition, a concentration of the methonium compound is preferable to be 0.025 mass % or more to 1.0 mass % or less. Further, in the polishing composition of the present invention, the alkanolamine compound is preferable to be at least one kind selected from a group consisting of DL-1-amino-2-propanol, 2-acetamide alcohol, 2-amino-2-methyl-1-propanol, 3-amino-1,2-propanediol, 2-amino-2-hydroxymethyl-1,3-propanediol, ethanolamine, and diethanolamine. The polishing composition of the present invention is preferable to contain the alkanolamine compound, and a concentration of the alkanolamine compound is preferable to be 0.01 mass % or more to 0.5 mass % or less. A concentration of the cerium oxide particles is preferable to be 0.05 mass % or more to 2 mass% or less.

A polishing method of the present invention comprise bringing a surface to be polished of an object to be polished into contact with a polishing pad while a polishing composition is supplied to the polishing pad on a polishing platen, and polishing by a relative movement between the surface to be polished of the object to be polished and the polishing pad, wherein the polishing composition is the composition of the present invention, and the object to be polished is a semiconductor substrate.

According to the present invention, a polishing composition and a polishing method using the polishing composition, can be provided, the polishing composition being usable for polishing of a surface to be polished where a silicon-based material including a silicon nitride or a silicon oxynitride and a silicon oxide is film-formed in a semiconductor device substrate, which polishes a silicon nitride film or a silicon oxynitride film at a high speed, and which enables polishing at a polishing speed ratio of 0.35 or more of the silicon nitride film or the silicon oxynitride film in relation to the silicon oxide film.

Hereinafter, embodiments of the present invention will be described by using a drawing, a table, a formula, an example, and so on. Note that such drawing, table, formula, example, and so on, as well as description are intended only to exemplify the present invention but not to limit the scope of the present invention. Other embodiments can belong to the category of the present invention as long as they conform to the spirit of the present invention.

### Polishing Composition

A polishing composition of the present invention is used for polishing of a surface to be polished of a semiconductor device substrate on which a silicon-based material including a silicon nitride or a silicon oxynitride, and a silicon oxide is film-formed, and is a composition for polishing a silicon-based object chemically and mechanically.

The polishing composition of the present invention is a composition which contains cerium oxide particles and at least one kind of nitride film polishing accelerating agent selected from a group consisting of a methonium compound and an alkanolamine compound. In the polishing composition, the alkanolamine compound is a primary or secondary alkanolamine compound, an average secondary particle diameter of the cerium oxide particles is 50 nm or more to 160 nm or less, and a concentration of the methonium compound is 1.0 mass % or less, and the polishing composition has a pH of 3.5 or more to less than 6 and a state of slurry.

According to the polishing composition of the present invention, a ratio of a polishing speed of the silicon nitride film or the silicon oxynitride film in relation to the silicon oxide film is preferable to be 0.35 or more, is more preferable to be 0.5 or more, and is further preferable to be 0.9 or more. By performing polishing in such a range, it becomes possible to suppress excessive polishing of the silicon oxide film while maintaining a high polishing speed of the silicon nitride film or the silicon oxynitride film.

Note that the pH of the polishing composition of the present invention is 3.5 or more to less than 6. In order to adjust the pH to be in the aforementioned range, a later-described pH adjusting agent can be added. When the pH is set to be 3.5 or more to less than 6, the polishing speed of the silicon nitride film or the silicon oxynitride film is high. When the pH is less than 3.5, the polishing speed of the silicon nitride film or the silicon oxynitride film is low, and when the pH is 6 or more, dispersion stability of the cerium oxide particles being abrasive particles is worsened. Hereinafter, each component of the polishing composition of the present invention and the pH adjusting agent will be described in detail.

(Polishing Abrasive Particle)

An average particle diameter of the cerium oxide contained in the polishing composition of the present invention is 50 nm or more to 160 nm or less. As a result that polishing of a silicon-based object to be polished constituted with a silicon nitride or a silicon oxynitride and a silicon oxide is performed with a cerium oxide (ceria) particle having an average particle diameter in the above-described range by a chemical and mechanical action, polishing is accelerated. When the average particle diameter is less than 50 nm, a mechanical action is weak and a polishing speed is reduced, and when the average particle diameter exceeds 160 nm, a scratch or the like might occur by a mechanical damage to a surface to be polished. The average particle diameter of the cerium oxide particles is preferable to be 60 nm or more to 130 nm or less.

Note that the cerium oxide particles contained as abrasive particles exist as aggregated particles (secondary particles) in which primary particles are aggregated in a liquid, and thus the preferable particle diameter of the cerium oxide is represented by an average secondary particle diameter (average aggregated-particle diameter). The average particle diameter is obtained by measurement using an abrasive particle liquid to be used for preparation of a polishing composition with a particle size distribution analyzer using dynamic light scattering, for example, in the abrasive particle liquid, cerium oxide particles being dispersed in a dispersion medium such as pure water

A content ratio (concentration) of the cerium oxide particles of the polishing composition of the present invention is preferable to be 0.05 mass % or more to 2 mass % or less in order to obtain a sufficient polishing speed. When the content ratio of the cerium oxide particle is less than 0.05 mass %, it is difficult to obtain a sufficiently high polishing speed, and when the content ratio exceeds 2 mass %, there is a risk that a scratch occurrence frequency in a polished surface increases or that adhesion remaining of the abrasive particle to a wafer increases in wafer cleaning after polishing, due to reduction of dispersibility or increase of the number of coarse particles included in a slurry. A more preferable content ratio is 0.1 mass % or more to 1.0 mass % or less, and a further preferable content ratio is 0.2 mass % or more to 0.6 mass % or less.

(Silicon Nitride Film Polishing Accelerating Agent)

The methonium compound and the alkanolamine compound contained in the polishing composition of the present invention are polishing accelerating agents for a silicon nitride film or a silicon oxynitride film. It is conceived that the methonium compound and the alkanolamine compound contribute to generation of a reaction layer of Si(OH)₄ in a film surface by a chemical action with the silicon nitride film or silicon oxynitride film surface, though a reason is not exactly known. Since such a reaction layer is able to be quickly removed by an abrasive particle, it is conceived that acceleration of reaction layer generation enables polishing of the silicon nitride film or the silicon oxynitride film at a high polishing speed.

In the above described methonium compound, the number of carbon of a main chain is preferable to be 2 to 7 and is more preferable to be 4 to 7. When the number of carbon is less than 2, a polishing acceleration effect is insufficient, and when the number of carbon exceeds 7, dispersibility of the cerium oxide particles being the abrasive particles might deteriorate.

In a case where the methonium compound is contained as the nitride film polishing accelerating agent, its concentration (content ratio) is preferable to be 0.025 mass % or more to 1.0 mass % or less and is more preferable to be 0.04 mass % or more to 0.6 mass % or less, with an entire amount of the polishing composition being 100 mass %. When the concentration is less than 0.025 mass %, the polishing acceleration effect is insufficient, and when the concentration exceeds 1.0 mass %, the polishing speed is reduced on the contrary, and further dispersibility of the cerium oxide particles might deteriorate.

As concrete examples of the methonium compound used in the present invention, there can be cited dimethonium bromide, pentamethonium bromide, pentamethonium iodide, hexamethonium chloride, hexamethonium chloride dihydrate, heptamethonium bromide, heptamethonium iodide, heptamethonium chloride, and so on. In particular, hexamethonium chloride and hexamethonium chloride dihydrate are preferable.

The above-described alkanolamine compound is preferable to be a primary or secondary amine selected from a group consisting of DL-1-amino-2-propanol, 2-acetamide alcohol, 2-amino-2-methyl-1-propanol, 3-amino-1,2-propanediol, 2-amino-2-hydroxymethyl-1,3-propanediol, ethanolamine, and diethanolamine. If the alkanolamine comprises a tertiary amine, the polishing speed of the silicon nitride film may be reduced.

In a case where the alkanolamine compound is contained, its concentration (content ratio) is preferable to be 0.01 mass % or more to 0.5 mass % or less, and is more preferable to be 0.05 mass % or more to 0.3 mass % or less. When the concentration is less than 0.01 mass %, the polishing acceleration effect is insufficient, and when the concentration exceeds 0.5 mass %, dispersibility of the cerium oxide particles tends to deteriorate.

(pH Adjusting Agent)

A pH of the polishing composition of the present invention can be adjusted by addition and compounding of an acid or a basic compound being a pH adjusting agent. As the acid, usable is an inorganic acid such as a nitric acid, a sulfuric acid, a phosphoric acid, and a hydrochloric acid. Use of the nitric acid is preferable. As the basic compound, usable is ammonia, a potassium hydroxide, a sodium hydroxide, and a quaternary ammonium compound such as tetramethylammonium. Use of potassium hydroxide is preferable.

A content ratio (concentration) of the above acid or basic compound is set to an mount to adjust the pH of the polishing composition to the above-described predetermined range (pH is 3.5 or more to less than 6, more preferably 3.5 or more to 5 or less).

(Dispersion Medium)

In the polishing composition of the present invention, water is contained as a dispersion medium. Water is a medium for stably dispersing cerium oxide particles and for dispersing and dissolving the other components. Water is not limited in particular, but pure water, ultrapure water, and ion-exchange water (deionized water) are preferable in view of an influence on the compounded components, mixture of impurities, an influence on a pH, and so on.

(Preparation and Optional Components of Polishing Composition)

When in use, the polishing composition of the present invention is prepared to contain the predetermined ratios of the aforementioned components, the cerium oxide particles uniformly dispersed and the other components being in a mixed state of uniformly dissolved. For mixture, a stirring and mixing method generally used for manufacturing of a polishing composition, for example, a stirring and mixing method by an ultrasonic dispersion machine, a homogenizer, or the like can be adopted. The polishing composition according to the present invention does not necessarily have to be supplied to a polishing site as a mixture in which constituent polishing components are all mixed in advance. The polishing components may be mixed to form the polishing composition at a time of supply to the polishing site.

The polishing composition of the present invention can appropriately contain an aggregation preventing agent or a dispersing agent, a lubricant, a viscosity imparting agent or a viscosity adjusting agent, an antiseptic agent, or the like as necessary, as long as not departing from the spirit of the present invention.

### Polishing Target

A polishing target (object to be polished) to be polished by the polishing composition of the present invention is a silicon-based object including a silicon nitride or a silicon oxynitride and a silicon oxide. More detailedly, the polishing composition of the present invention is used in a gate forming process in a transistor.

### Polishing Method

As a method of polishing a surface to be polished of a semiconductor device substrate in which a silicon-based material being a polishing target is film-formed, the silicon-based material being constituted with a silicon nitride or a silicon oxynitride, and at least one kind selected from a group composed of a silicon oxide, polysilicon and amorphous silicon, by using the polishing composition of the present invention, a polishing method is preferable in which polishing is performed by a relative movement between the surface to be polished of the polishing target and a polishing pad which are brought into contact with each other while the polishing composition is supplied to the polishing pad.

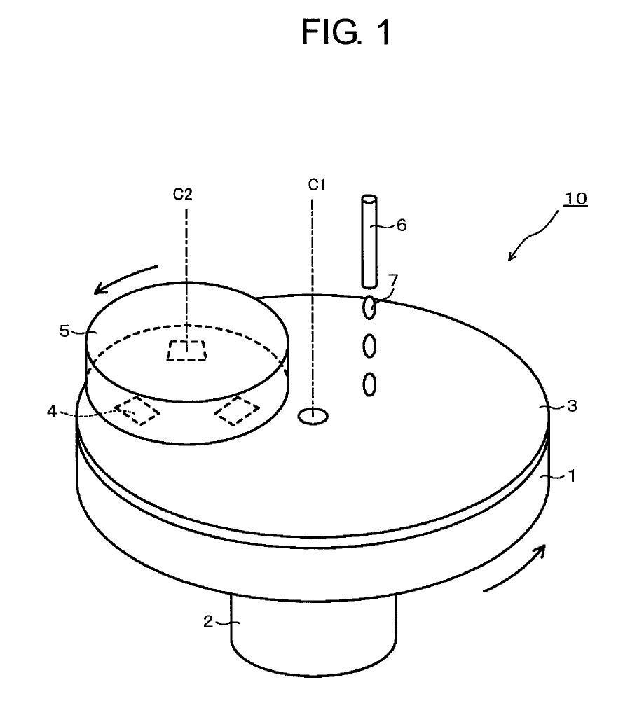

In the above-described polishing method, a conventional known polishing apparatus is usable as a polishing apparatus. FIG. 1 shows an example of the polishing apparatus usable in the embodiment of the present invention, but the polishing apparatus used in the embodiment of the present invention is not limited to one having such a structure.

In a polishing apparatus 10 shown in FIG. 1, a polishing platen 1 is provided in a state of being supported rotatable around its vertical axis C1, and the polishing platen 1 is driven to rotate in a direction indicated by an arrow in the drawing by a platen driving motor 2. On an upper surface of the polishing platen 1, a known polishing pad 3 is affixed.

On the other hand, at a position deviated from the axis C1 on the polishing platen 1, a substrate holding member (carrier) 5 is supported in a rotatable manner around its axis C2 and in a movable manner in an axis C2 direction, the substrate holding member 5 holding a semiconductor device substrate 4 in which the silicon-based material is film-formed on its lower surface by suction or by using a holding frame or the like. The substrate holding member 5 is constructed to be rotated in the direction indicated by the arrow by a not-shown workpiece driving motor or by a rotational moment received from the above-described polishing platen 1. The polishing target 4 is held in the lower surface of the substrate holding member 5, that is, in a surface facing the above-described polishing pad 3. The semiconductor device substrate 4 is pressed against the polishing pad 3 with a predetermined load.

Further, a dripping nozzle 6 or the like is provided near the substrate holding member 5, so that the polishing composition 7 of the present invention fed out from a not-shown tank is supplied onto the polishing platen 1.

In polishing by this polishing apparatus 10, in a state where the polishing platen 1 and the polishing pad 3 pasted thereon as well as the substrate holding member 5 and the semiconductor device substrate 4 held on its lower surface are driven to rotate around respective axes by the platen driving motor 2 and the workpiece driving motor, while the polishing composition 7 is supplied to a surface of the polishing pad 3 from the dripping nozzle 6 or the like, the semiconductor device substrate 4 held by the substrate holding member 5 is pressed against the polishing pad 3. Thereby, the surface to be polished of the semiconductor device substrate 4, that is, the surface facing the polishing pad 3 is chemically and mechanically polished.

The substrate holding member 5 may make not only a rotational movement but also a linear movement. Further, the polishing platen 1 and the polishing pad 3 are not necessarily ones which make rotational movements, and may move in one direction by a belt system, for example.

A condition of polishing by such a polishing apparatus 10 is not limited in particular, but a polishing pressure can be further heightened to improve the polishing speed by giving a load to the substrate holding member 5 in pressing against the polishing pad 3. The polishing pressure is preferable to be about 5 to 50 kPa, and is more preferable to be about 7 to 35 kPa in view of uniformity of the polishing speeds, flatness of the polished surface, and prevention of a polishing defect such as a scratch in the surface to be polished. The numbers of rotations of the polishing platen 1 and the substrate holding member 5 are preferable to be about 50 to 500 rpm, but is not limited thereto. Further, a supply amount of the polishing composition 7 is appropriately adjusted and selected according to constituent materials of the surface to be polished, a composition of the polishing composition 7, the above-described polishing condition, and so on.

As the polishing pad 3, one made of general nonwoven fabric, foamed polyurethane, a porous resin, a nonporous resin, or the like is usable. Further, in order to accelerate supply of the polishing composition 7 to the polishing pad 3 or to make a predetermined amount of the polishing composition 7 stay in the polishing pad 3, the surface of the polishing pad 3 may be subjected to a grooving processing of a lattice-shape, a concentric shape, a spiral shape, or the like. Further, as necessary, polishing may be performed while a pad conditioner is brought into contact with the surface of the polishing pad 3 to perform conditioning of the surface of the polishing pad 3.

### EXAMPLES

Hereinafter, the present invention will be described concretely by working examples and comparative examples, but the present invention is not limited to those working examples. Examples 1 to 17 are working examples of the present invention, while examples 18 to 25 are comparative examples.

### Examples 1 to 25

### (1) Preparation of Polishing Composition

(1-1) Polishing compositions of the examples 1 to 25 were each prepared as described below. First, each abrasive particle liquid in which cerium oxide particles with an average particle diameter indicated in Table 1 was used and deionized water was further added to each abrasive particle liquid followed by five-minute stirring, and ultrasonic dispersion and filtering were applied, whereby 500 g of abrasive particle liquid P was prepared to have a concentration twice as large as a concentration (%) of the abrasive particle in a polishing composition indicated in Table 1. Hereinafter, “%” in the example and the comparative examples indicates a proportion of such a mass ratio.

(1-2) Next, each kind of silicon nitride film polishing accelerating agent (polishing accelerating agent) was added into the deionized water at a concentration twice as large as a concentration indicated in Table 1, and further, a nitric acid or a potassium hydroxide being a pH adjusting agent was dissolved so that a predetermined pH indicated in Table 1 could be obtained when mixed with the abrasive particle liquid P, whereby 500 g of additive liquid Q was prepared.

(1-3) Next, 500 g of abrasive particle liquid P and 500 g of additive liquid Q were mixed while being stirred, whereby 1 kg of each kind of polishing composition shown in

Table 1 was prepared. Note that measurement of particle size distribution of the cerium oxide particles was performed by using the abrasive particle liquid P by a laser scattering-diffraction apparatus (manufactured by Horiba, Ltd., trade name: LA-920). Further, a pH was measured by pH81-11 manufactured by Yokogawa Electric Corporation. Note that since the examples 22, 23 do not contain a polishing accelerating agent, 1 kg of polishing composition is each prepared as a result that 500 g of abrasive particle liquid P and 500 g of deionized water are mixed while being stirred.

TABLE 1

| | | Concentration of | Average particle | | | Concentration of polishing |
|---|---|---|---|---|---|---|
| | Abrasive | abrasive particle | diameter | | Kind of polishing | accelerating agent |
| | particle | (mass %) | (nm) | pH | accelerating agent | (mass %) |
| Example 1 | Cerium oxide | 0.4 | 112 | 4 | DL-1-amino-2-propanol | 0.12 |
| Example 2 | Cerium oxide | 0.4 | 112 | 4 | 2-acetamide ethanol | 0.17 |
| Example 3 | Cerium oxide | 0.4 | 112 | 4 | 2-amino-2-methyl-1-propanol | 0.15 |
| Example 4 | Cerium oxide | 0.4 | 112 | 4 | 3-amino-1,2-propanediol | 0.15 |
| Example 5 | Cerium oxide | 0.4 | 112 | 4 | 2-amino-2-hydroxymethyl-1,3-propanediol | 0.1 |
| Example 6 | Cerium oxide | 0.4 | 112 | 4 | 2-amino-2-hydroxymethyl-1,3-propanediol | 0.2 |
| Example 7 | Cerium oxide | 0.4 | 112 | 4 | Monoethanolamine | 0.1 |
| Example 8 | Cerium oxide | 0.4 | 112 | 5 | Monoethanolamine | 0.1 |
| Example 9 | Cerium oxide | 0.4 | 112 | 4 | Monoethanolamine | 0.3 |
| Example 10 | Cerium oxide | 0.4 | 112 | 4 | Diethanolamine | 0.17 |
| Example 11 | Cerium oxide | 0.4 | 112 | 4 | Hexamethonium chloride dehydrate | 0.1 |
| Example 12 | Cerium oxide | 1 | 112 | 4 | Hexamethonium chloride dehydrate | 0.1 |
| Example 13 | Cerium oxide | 0.4 | 112 | 4 | Hexamethonium chloride dehydrate | 0.05 |
| Example 14 | Cerium oxide | 0.4 | 112 | 4 | Hexamethonium chloride dehydrate | 0.2 |
| Example 15 | Cerium oxide | 0.4 | 112 | 4 | Hexamethonium chloride dehydrate | 0.5 |
| Example 16 | Cerium oxide | 0.2 | 112 | 4 | Hexamethonium chloride dehydrate | 0.05 |
| Example 17 | Cerium oxide | 0.4 | 80 | 4 | Hexamethonium chloride dehydrate | 0.1 |
| Example 18 | Cerium oxide | 0.4 | 180 | 4 | Hexamethonium chloride dehydrate | 0.1 |
| Example 19 | Cerium oxide | 0.4 | 180 | 4 | Monoethanolamine | 0.1 |
| Example 20 | Cerium oxide | 0.4 | 180 | 4 | 2-amino-2-hydroxymethyl-1,3-propanediol | 0.1 |
| Example 21 | Cerium oxide | 0.2 | 112 | 4 | Hexamethonium chloride dehydrate | 0.02 |
| Example 22 | Cerium oxide | 0.4 | 112 | 4 | — | — |
| Example 23 | Cerium oxide | 0.4 | 80 | 4 | — | — |
| Example 24 | Cerium oxide | 0.4 | 112 | 3 | Monoethanolamine | 0.1 |
| Example 25 | Cerium oxide | 0.4 | 112 | 4 | Triethanolamine | 0.24 |

(Polishing Speed Evaluation)

By using each kind of polishing composition, polishing speeds of a silicon nitride film and a silicon oxide film are evaluated.

(Evaluation Method)

Polishing was performed by using a CMP polishing apparatus (manufactured by Applied Materials, Inc., trade name: Mirra). As a polishing pad, a two layer pad IC-1400 K-groove manufactured by Rodel, Inc. was used, and for conditioning of the polishing pad, MEC100-PH3.5L manufactured by Mitsubishi Materials Corporation was used. For polishing of the each polishing composition of the examples 1 to 25, a polishing pressure was 13.8 kPa, the numbers of rotations of a polishing platen and a polishing head were 77 rpm and 73 rpm for each example, and a polishing time was one minute for each example.

For semiconductor substrates as objects to be polished, an eight-inch silicon wafer substrate on which a silicon nitride film was formed, and an eight-inch silicon wafer substrate on which a silicon oxide film was formed were used, and for measurement of polishing speeds, a thicknessmeter UV-1280SE manufactured by KLA-Tencor Corporation was used, whereby the polishing speed (angstrom/minute) was calculated from a difference between a thickness before polishing and a thickness after polishing. Results are shown in Table 2. Note that in Table 2, “angstrom” is represented by a symbol “A”.

TABLE 2

| | Silicon | Silicon | Silicon |
|---|---|---|---|
| | nitride | oxide | nitride/ |
| | polishing | polishing | silicon oxide |
| | speed | speed | polishing speed |
| | (A/min) | (A/min) | ratio |
| Example 1 | 640 | 867 | 0.74 |
| Example 2 | 500 | 1011 | 0.49 |
| Example 3 | 601 | 915 | 0.66 |
| Example 4 | 663 | 972 | 0.68 |
| Example 5 | 764 | 1370 | 0.56 |
| Example 6 | 779 | 1100 | 0.71 |
| Example 7 | 620 | 946 | 0.66 |
| Example 8 | 661 | 1797 | 0.37 |
| Example 9 | 768 | 960 | 0.80 |
| Example 10 | 617 | 983 | 0.63 |
| Example 11 | 640 | 320 | 2.00 |
| Example 12 | 631 | 307 | 2.06 |
| Example 13 | 385 | 419 | 0.92 |
| Example 14 | 468 | 159 | 2.94 |
| Example 15 | 391 | 203 | 1.93 |
| Example 16 | 209 | 233 | 0.90 |
| Example 17 | 92 | 98 | 0.94 |
| Example 18 | 125 | 720 | 0.17 |
| Example 19 | 27 | 1276 | 0.02 |
| Example 20 | 100 | 1652 | 0.06 |
| Example 21 | 225 | 1347 | 0.17 |
| Example 22 | 503 | 2975 | 0.17 |
| Example 23 | 40 | 362 | 0.11 |
| Example 24 | 19 | 223 | 0.09 |
| Example 25 | 31 | 1002 | 0.03 |

As is known from Table 2, the examples 1 to 17 being polishing compositions of the present invention indicate higher polishing speeds to the silicon nitride films compared with the comparative examples, that is, the examples 18 to 20 having abrasive particles with average abrasive particle diameters out of the range of the present invention, the example 21 having the concentration of the polishing accelerating agent out of the range of the present invention, the examples 22, 23 not containing a polishing accelerating agent, the example 24 having a pH out of the range of the present invention, and the example 25 containing a tertiary alkanolamine out of the range of the present invention, and indicate high values of 0.35 or more in polishing speed ratio of the silicon nitride film in relation to the silicon oxide film.

Since the polishing composition of the present invention can polish a silicon nitride or a silicon oxynitride at a high polishing speed and the silicon nitride or the silicon oxynitride exhibits a suitable polishing speed ratio to a silicon oxide, the polishing composition of the present invention can be applied to a manufacturing process of a semiconductor device, particularly to a planarization process in a gate forming process in a multi-layer wiring forming process.

Configurations described in the aforementioned embodiments are merely presented schematically, and composition, materials or the like of each construction are examples only. Therefore, the present invention is not limited by the embodiments hereinabove and can be altered in various forms without departing from the scope of the technical idea indicated in the scope of what is claimed.

What is claimed is:

1. A polishing composition, comprising:
cerium oxide particles; and
at least one kind of nitride film polishing accelerating agent selected from a group consisting of a methonium compound and an alkanolamine compound;
wherein the alkanolamine compound is a primary or secondary alkanolamine compound, an average secondary particle diameter of the cerium oxide particles is 50 nm or more to 160 nm or less, a concentration of the methonium compound is 1.0 mass % or less, and a pH is 3.5 or more to less than 6.

2. The polishing composition according to claim 1,
wherein the number of carbon of a main chain of the methonium compound is 2 to 7.

3. The polishing composition according to claim 1, comprising the methonium compound, wherein a concentration of said methonium compound is 0.025 mass % or more to 1.0 mass % or less.

4. The polishing composition according to claim 1,
wherein the alkanolamine compound is at least one kind selected from a group consisting of DL-1-amino-2-propanol, 2-acetamide alcohol, 2-amino-2-methyl-1-propanol, 3-amino-1,2-propanediol, 2-amino-2-hydroxymethyl-1,3-propanediol, ethanolamine, and diethanolamine.

5. The polishing composition according to claim 1, comprising the alkanolamine compound, wherein a concentration of said alkanolamine compound is 0.01 mass % or more to 0.5 mass % or less.

6. The polishing composition according to claim 1,
wherein a concentration of said cerium oxide particles is 0.05 mass % or more to 2 mass % or less.

7. A polishing method comprising:
bringing a surface to be polished of an object to be polished into contact with a polishing pad while a polishing composition is supplied to the polishing pad on a polishing platen; and
polishing by a relative movement between the surface to be polished of the object to be polished and the polishing pad,
wherein the polishing composition is the composition according to claim 1, and the object to be polished is a semiconductor substrate.
